(19) United States
(12) Patent Application Publication
(10) Pub. No.: US 2025/0321504 A1
(43) Pub. Date: Oct. 16, 2025

(54) SUBSTRATE PROCESSING APPARATUS AND GAS SUPPLY METHOD

(71) Applicant: Tokyo Electron Limited, Tokyo (JP)

(72) Inventors: Naoki TAJIMA, Koshi City (JP); Masashi TSUCHIYAMA, Koshi City (JP)

(21) Appl. No.: 19/175,304

(22) Filed: Apr. 10, 2025

(30) Foreign Application Priority Data
Apr. 11, 2024 (JP) 2024-064104
Nov. 26, 2024 (JP) 2024-205694

(51) Int. Cl. G03F 7/00

(52) U.S. Cl. CPC G03F 7/70875; G03F 7/70808; G03F 7/70925; G03F 7/70933; G03F 7/70991

(57) ABSTRACT

A substrate processing apparatus includes at least one processing unit configured to process a substrate, a transfer area in which a transfer unit configured to transfer the substrate to the at least one processing unit, a duct configured to supply air supplied from an air source to the at least one processing unit, an intake supply configured to intake ambient air around the substrate processing apparatus to supply the air to the transfer area; and a supply pipe configured to connect the duct and the intake supply so that the air supplied from the air source, which flows through the duct, is supplied to the transfer area.

### CROSS-REFERENCE TO RELATED APPLICATIONS

This application is based upon and claims the benefit of priority from Japanese Patent Application Nos. 2024-064104 and 2024-205694, filed on Apr. 11, 2024 and Nov. 26, 2024, respectively, the entire contents of which are incorporated herein by reference.

### TECHNICAL FIELD

The present disclosure relates to a substrate processing apparatus and a gas supply method.

### BACKGROUND

Patent document 1 discloses a substrate processing apparatus which processes a substrate and includes a plurality of processing units that performs the same process on the substrate, and an air pressure control means that controls air pressure in the plurality of processing units so that processing results obtained by the plurality of processing units are substantially identical to each other.

### PRIOR ART DOCUMENT

### [Patent Document]

Patent Document 1: Japanese Laid-Open Patent Publication No. 2006-024638

### SUMMARY

According to one embodiment of the present disclosure, a substrate processing apparatus includes at least one processing unit configured to process a substrate, a transfer area in which a transfer unit configured to transfer the substrate to the at least one processing unit, a duct configured to supply air supplied from an air source to the at least one processing unit, an intake supply configured to intake ambient air around the substrate processing apparatus to supply the air to the transfer area; and a supply pipe configured to connect the duct and the intake supply so that the air supplied from the air source, which flows through the duct, is supplied to the transfer area.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing an outline of a configuration of a coating-developing apparatus used as a substrate processing apparatus.

FIG. 2 is a diagram schematically showing an outline of an internal configuration of a central portion of the coating-developing apparatus in a depth direction.

FIG. 3 is a diagram schematically showing an outline of an internal configuration of the coating-developing apparatus on a front side.

FIG. 4 is a diagram schematically showing an outline of an internal configuration of a rear side of the coating-developing apparatus.

FIG. 5 is a plan view of an interior of a delivery unit.

FIG. 6 is a top view showing an appearance of a left sub-block.

FIG. 7 is a diagram showing a connection form in which a duct and a transfer-area duct are connected to each other.

FIG. 8 is a diagram for explaining one example of a supply pipe.

FIG. 9 is a diagram for explaining one example of the duct.

FIG. 10 is a diagram for explaining another example of the duct.

FIG. 11 is a diagram for explaining another examples of the duct and the supply pipe.

FIG. 12 is a diagram for explaining another example of the supply pipe.

FIG. 13 is a diagram for explaining another examples of the duct and the supply pipe.

FIG. 14 is a diagram for explaining another example of the duct.

FIG. 15 is a diagram for explaining another example of the duct, in which a portion of the duct is illustrated in a cross section.

### DETAILED DESCRIPTION

Reference will now be made in detail to various embodiments, examples of which are shown in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a photolithography process in a manufacturing process of a semiconductor device, a series of processes is performed to form a desired resist pattern on a semiconductor wafer (hereinafter, referred to as a “wafer”) as a substrate. Examples of the series of processes may include a resist film forming process of supplying a resist solution onto the wafer to form a resist film on the wafer, an exposure process of exposing the resist film, and a developing process of supplying a developing solution to the exposed resist film to develop the exposed resist film. Among these processes, the processes other than the exposure process, such as the resist film forming process and the developing process, are performed in a coating-developing apparatus which is a substrate processing apparatus.

The coating-developing apparatus is provided with various processing units such as a liquid processing unit that performs liquid processing on the wafer. In addition, for example, clean air is supplied to the liquid processing unit in order to keep an internal atmosphere of the liquid processing unit clean. A duct is provided to supply this clean air. A clean air source and the liquid processing unit are connected to each other via the duct.

The coating-developing apparatus is further provided with a transfer unit that transfers the wafer to the processing unit. The clean air is supplied even to a transfer area in which the transfer unit is provided. In addition, there are cases in which ambient air intaken from around the coating-developing apparatus is supplied to the transfer area.

However, in a case in which a heat source such as electrical component exists around an air intake port, a temperature of the ambient air intaken and supplied to the transfer area rises. As a result, such high-temperature air may reach even the processing unit provided around the transfer area. This may make processing results obtained by the processing unit non-uniform in the place of the wafer. Specifically, for example, in a temperature adjustment unit provided adjacent to the transfer area to perform a temperature control processing, a temperature near to the transfer area in a temperature adjustment plate on which the wafer is placed is relatively increased due to the high-temperature air introduced from the transfer area. As a result, the adjustment of the temperature of the wafer by the temperature adjustment plate may become non-uniform in the plane of the wafer.

In addition, as a method of solving such a matter, there is a method of supplying air, a temperature of which is adjusted, to the transfer area, in a case in which a source of such temperature-adjusted air is connected to the transfer area via the duct. However, this method may cause an increase in footprint.

Therefore, a technology according to the present disclosure suppresses the influence heat from heat sources such as electrical components provided in a substrate processing apparatus, which includes a processing unit configured to process a substrate and a transfer area in which a transfer unit configured to transfer the substrate to the processing unit is provided, while suppressing the increase in footprint,

Hereinafter, the substrate processing apparatus according to the present embodiment will be described with reference to the drawings. In this specification and the drawings, elements having substantially the same functional configuration will be designated by the same reference numerals and redundant descriptions thereof will be omitted.

### <Coating-Developing Apparatus 1>

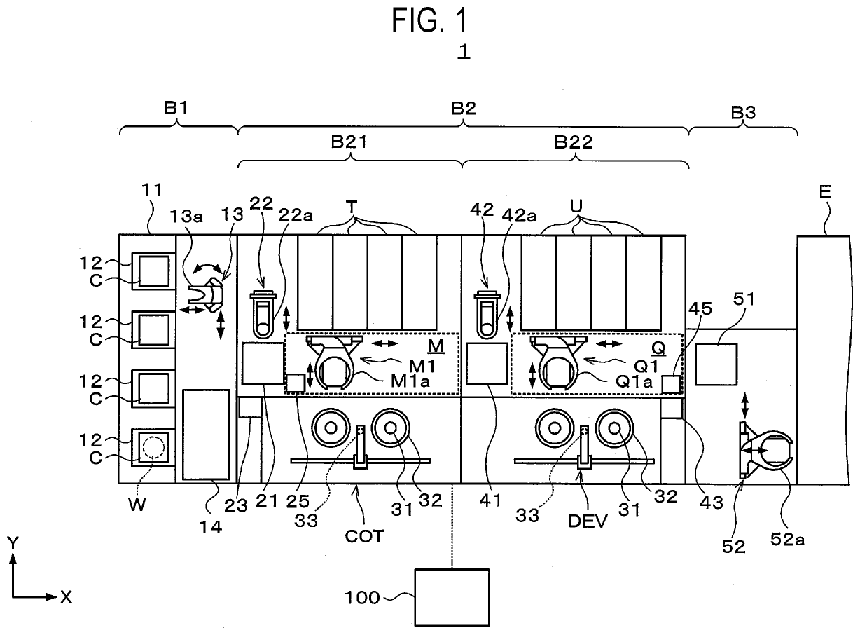

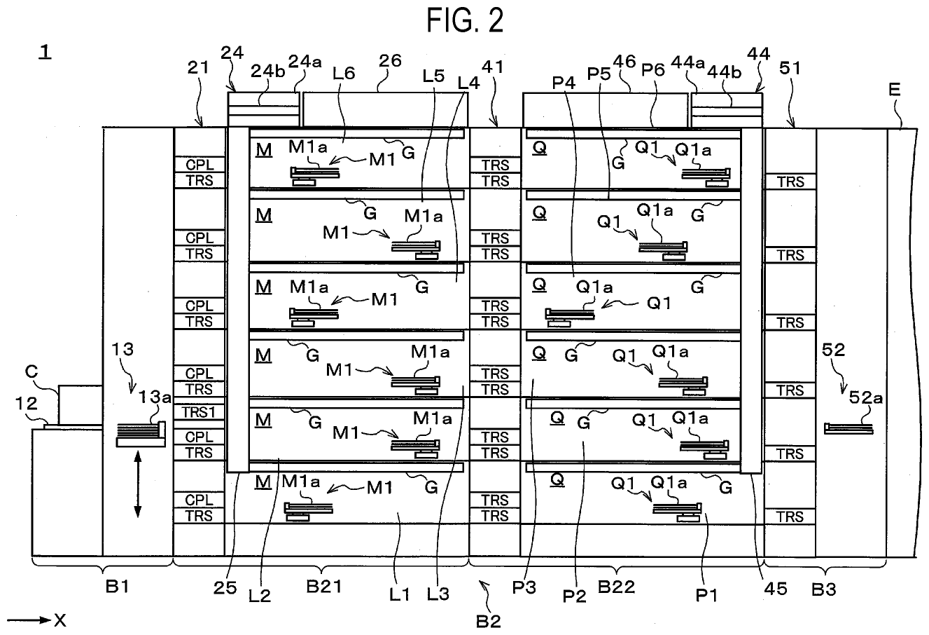

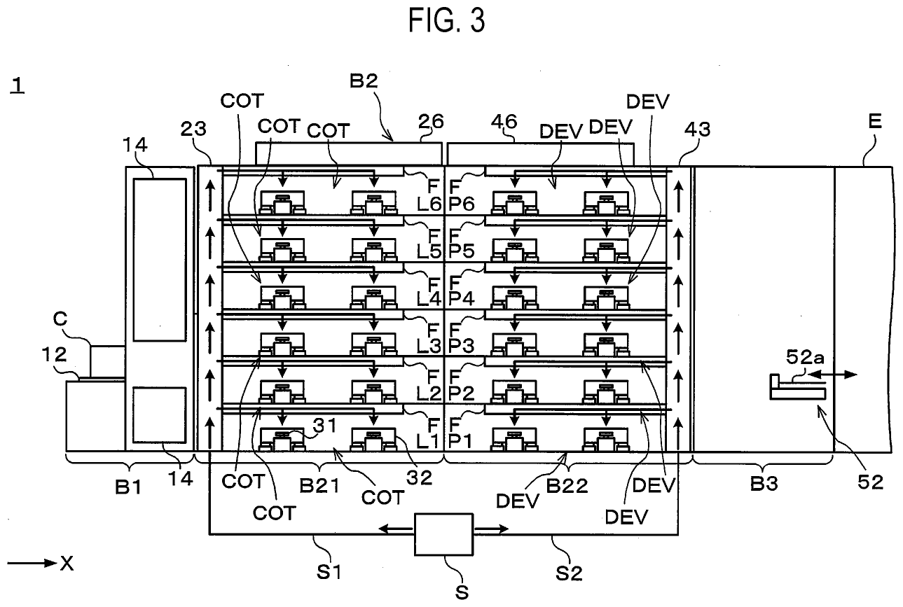

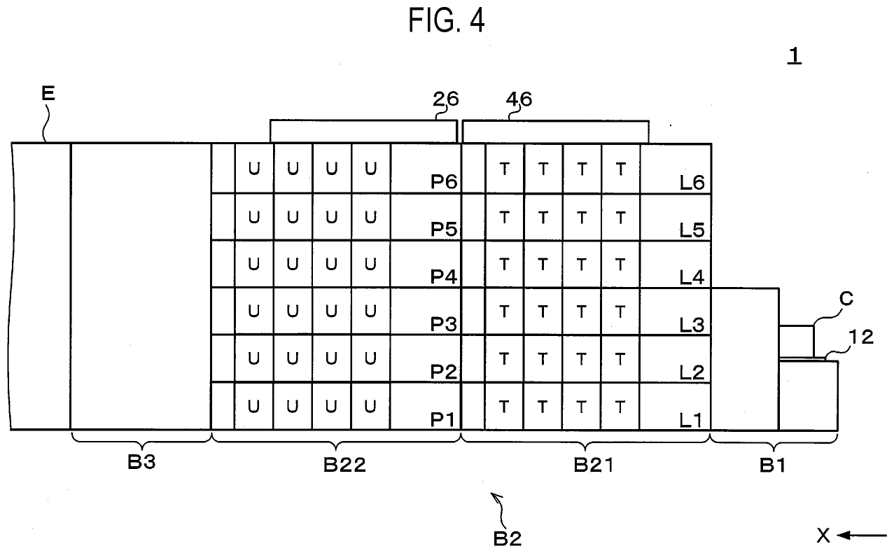

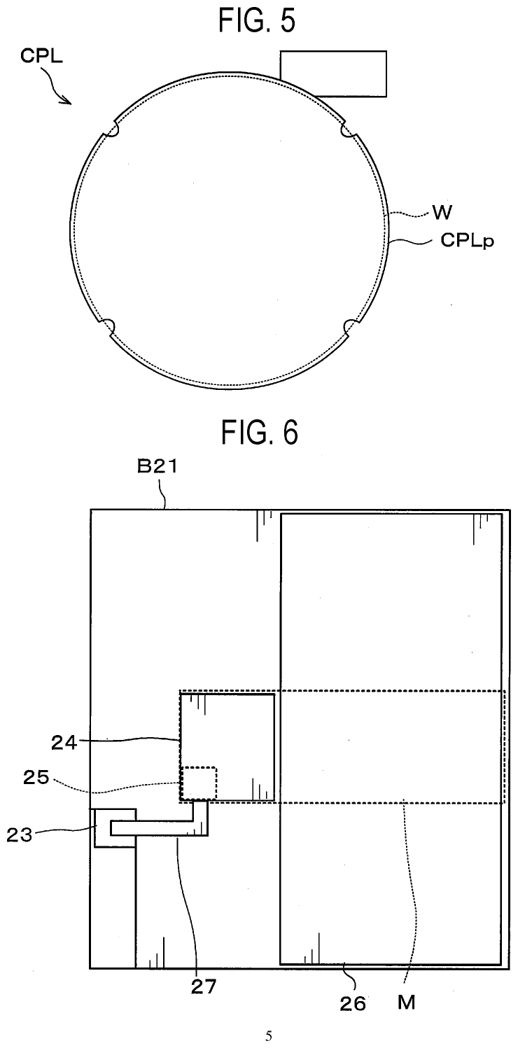

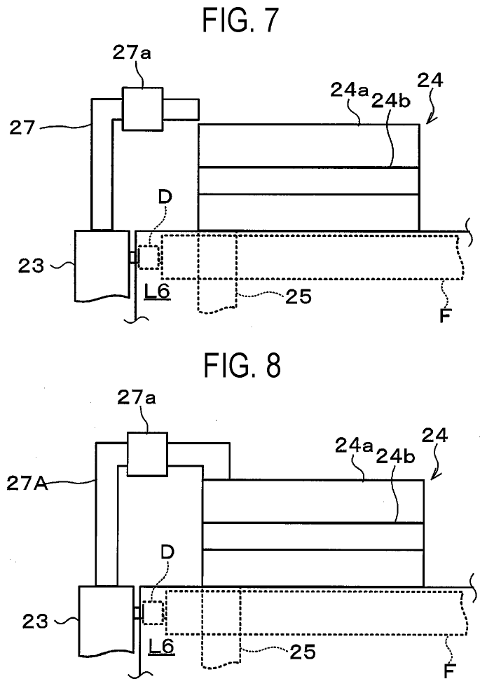

FIG. 1 is a plan view schematically showing an outline of a configuration of a coating-developing apparatus 1 used as the substrate processing apparatus. FIG. 2 is a diagram schematically showing an outline of an internal configuration of a central portion of the coating-developing apparatus in a depth direction. FIGS. 3 and 4 are diagrams schematically showing outlines of internal configurations of the coating-developing apparatus 1 on front and rear sides, respectively. FIG. 5 is a plan view of an interior of a delivery unit to be described later. FIG. 6 is a top view showing an appearance of a left sub-block to be described later. FIG. 7 is a diagram showing a connection form in which a duct and a transfer-area duct (to be described later) are connected to each other.

As shown in FIG. 1, in the coating-developing apparatus 1, a carrier block B1, a processing block B2, and an interface block B3 used as a relay block are provided to be arranged in this order in a width direction (X-direction in the drawing). In the following description, the width direction may be referred to as a right-left direction. An exposure apparatus E is connected to a right side (positive X-direction in the drawing) of the interface block B3.

The carrier block B1 is a block into and from which a carrier C for collectively transferring a plurality of wafers W as a plurality of substrates is loaded and unloaded. The carrier block B1 is provided with a carrier stage 11. For example, the carrier stage 11 includes a placement plate 12 on which the carrier C is placed when the carrier C is loaded into or unloaded from the outside of the coating-developing apparatus 1. A plurality of (four in an example shown in the drawing) placement plates 12 is provided in a depth direction (Y-direction in the drawing) perpendicular to the width direction (X-direction in the drawing) on a horizontal plane. Further, the carrier block B1 includes a transfer unit 13 provided between the carrier stage 11 and the processing block B2. The transfer unit 13 includes a transfer arm 13a configured to be extendible, movable vertically, rotatable about a vertical axis, and movable in the depth direction, and may transfer the wafer W between the carrier C placed on each placement plate 12 and a delivery tower 14 to be described later.

Further, an area on a front side (negative Y-direction in the drawing) of the carrier block B1 (specifically, an area on the front side of the carrier block B1 that does not interfere with the transfer unit 13) becomes an accommodation area 14. The accommodation area 14 accommodates a liquid feeding unit (not shown) that supplies a processing liquid to a liquid processing unit, an electrical component (not shown) that operates the liquid feeding unit and the like, or the like.

The processing block B2 is a block in which processing units for processing the wafers W before or after exposure are provided. In this embodiment, the processing block B2 is constituted with a plurality of (two in an example shown in the drawing) sub-blocks B21 and B22 provided step-by-step in the right-left direction (X-direction in the drawing). Hereinafter, the sub-block B21 on the side of the carrier block B1 is referred to as a left sub-block B21, and the sub-block B22 on the side of the interface block B3 is referred to as a right sub-block B22.

As shown in FIGS. 2 to 4, the left sub-block B21 include first to sixth layer blocks L1 to L6 stacked in the named order from the bottom. Likewise, the right sub-block B22 includes first to sixth layer blocks P1 to P6 stacked in the named order from the bottom. Each of the layer blocks L1 to L6 and P1 to P6 includes various processing units.

The left sub-block B21 is provided with a delivery tower 21 on the side of the carrier block B1 in a central portion of the left sub-block B21 in the depth direction thereof (Y-direction in the drawing) so as to span the first to sixth layer blocks P1 to P6. The delivery tower 21 is formed by vertically stacking a plurality of delivery units one above another. The delivery tower 21 is provided with the delivery units at height positions corresponding to the first to sixth layer blocks L1 to L6. Specifically, the delivery tower 21 is provided with delivery units TRS11 and CPL11 at positions corresponding to the first layer block L1. Similarly, the delivery tower 21 is provided with delivery units TRS and delivery units CPL at positions corresponding to the second to sixth layer blocks L2 to L6, respectively. The delivery unit TRS and the delivery unit CPL are similar in configuration to each other. However, only the delivery unit CPL is a temperature adjustment unit, which is a type of processing unit, which includes a temperature adjustment plate for adjusting the temperature of the wafer W placed thereon. For example, the delivery unit CPL functions as a cooling unit, which is an example of the temperature adjustment unit. As shown in FIG. 5, the delivery unit CPL includes a cooling plate CPLp that cools the wafer W as the temperature adjustment plate. For example, a flow path (not shown) through which a cooling refrigerant circulates is formed inside the cooling plate CPLp. Each of the delivery units CPL cools the wafer W to, for example, a temperature lower than room temperature, specifically, cools the wafer W to a temperature substantially equal to a processing temperature in the liquid processing unit.

In addition, the delivery tower 21 is provided with the delivery unit TRS1 at a height position to which the transfer unit 13 in the carrier block B1 is accessible, specifically, as shown in FIG. 2, at a position between a delivery unit CPL12 of the second layer block L2 and a delivery unit TRS13 of the third layer block L3. The delivery unit TRS1 is similar in configuration to the delivery unit TRS. For example, the delivery unit TRS1 is used when loading and unloading the wafer between the left sub-block B21 and the carrier block B1.

As shown in FIG. 1, a transfer unit 22 is provided at a rear side of the delivery tower 21 (the positive Y-direction in the drawing). The transfer unit 22 includes a transfer arm 22a configured to be extendible and vertically movable, and may transfer the wafer W between the delivery units of the delivery tower 21.

Next, the first to sixth layer blocks L1 to L6 of the left sub-block B21 will be described. In FIG. 1, a configuration of the first layer block L1 in the left sub-block B21 is shown. Hereinafter, the first layer block L1 will be described in detail

As shown in FIG. 1, a transfer area M is formed in the center of the first layer block L1 in the depth direction so as to extend from the delivery tower 21 in the width direction. That is, in a plan view, the delivery tower 21 is provided at a position adjacent to the transfer area M in the extension direction of the transfer area M.

Various processing units are provided in an area in front of the transfer area M (the negative Y-direction in the drawing) and an area in the rear (the positive Y-direction in the drawing) of the first layer block L1.

Specifically, the resist film formation unit COT, which is the liquid processing unit that performs the liquid processing on the wafer W using the processing liquid, is provided in the area in front of the first layer block L1. Vertical units T including various units are provided in the area in the rear of the first layer block L1.

The resist film formation unit COT forms the resist film on the wafer W. The resist film formation unit COT includes a spin chuck 31 that rotates the wafer W while holding the wafer W, and a cup 32 that surrounds the wafer W on the spin chuck 31 to collect the processing liquid scattering from the wafer W. Two pairs of the spin chucks 31 and the cups 32 are provided in the width direction. The resist film formation unit COT is provided with a nozzle 33 that blows a resist liquid as the processing liquid onto the wafer W held on the spin chuck 31. The nozzle 33 is configured to be movable between the cups 32 and is shared by the cups 32.

A plurality of vertical units T (four in an example shown the drawing) is provided in the width direction (the X-direction in the drawing). Each of the vertical units T includes a heating unit that performs a heat treatment on the wafer W. The heating units are stacked vertically in, for example, two stages, in each vertical unit T.

In addition, in the first layer block L1, a transfer unit M1 is provided in the transfer area M described above. The transfer unit M1 includes a transfer arm M1a configured to be extendible, movable vertically, rotatable about a vertical axis, and movable in the depth direction (the X-direction in the drawing). The transfer arm M1a may deliver the wafer W between the delivery tower 21 and the resist film formation unit COT, and between the resist film formation unit COT and the vertical unit T. Further, the transfer arm M1a may access a delivery tower 41 (to be described later) in the right sub-block B22.

The second to sixth layer blocks L2 to L6 are similar in configuration to, for example, the first layer block L1.

The right sub-block B22 includes the delivery tower 41 at a central portion in the depth direction (the Y-direction in the drawing), which is a position adjacent to the transfer area M of the left sub-block B21 in the width direction (the X-direction in the drawing). As shown in FIG. 2, the delivery tower 41 is provided so as to span the first to sixth layer blocks P1 to P6 of the right sub-block B22.

In the delivery tower 41, a plurality of delivery units is stacked vertically one above another. The delivery tower 41 is provided with delivery units at height positions corresponding the first to sixth layer blocks L1 to L6 and the first to sixth layer blocks P1 to P6. Specifically, the delivery tower 41 includes the delivery units TRS at a position corresponding to the first layer block L1 and the first layer block P1, a position corresponding to the second layer block L2 and the second layer block P2, a position corresponding to the third layer block L3 and the third layer block P3, a position corresponding to the fourth layer block L4 and the fourth layer block P4, a position corresponding to the fifth layer block L5 and the fifth layer block P5, and a position corresponding to the sixth layer block L6 and the sixth layer block P6.

As shown in FIG. 1, the right sub-block B22 is provided with a transfer unit 42 at a rear side of the delivery tower 41 (the positive Y-direction in the drawing). The transfer unit 42 includes a transfer arm 42a configured to be extendible and vertically movable, and may transfer the wafer W between the delivery units of the delivery tower 41.

Next, the first to sixth layer blocks P1 to P6 of the right sub-block B22 will be described. In FIG. 1, a configuration of the first layer block P1 of the right sub-block B22 is shown.

The first layer block P1 of the right sub-block B22 and the first layer block L1 of the left sub-block B21 include different types of liquid processing units provided at the front side. The first layer block P1 of the right sub-block B22 is provided with, instead of the resist film formation unit COT, a developing unit DEV that performs a development process on the wafer W after exposure as the liquid processing unit. A developing solution is supplied as the processing liquid from the nozzle 33 of the developing unit DEV. Other configurations of the first layer block P1 of the right sub-block B22 are similar to those of the first layer block L1 of the left sub-block B21.

Further, the second to sixth layer blocks P2 to P6 are similar in configuration to, for example, the first layer block P1. In FIG. 1 and the like, a transfer area provided in the first to sixth layer blocks P1 to P6 is indicated by Q, and a vertical unit is indicated by U. Further, a transfer unit provided in the transfer area Q is indicated by Q1, and a transfer arm of the transfer unit Q1 is indicated by Q1a. The transfer arm Q1a may deliver the wafer W between the delivery tower 41 and the development unit DEV, and between the development unit DEV and the vertical unit U. Further, the transfer arm Q1a may access a delivery tower 51 (to be described later) in the interface block B3.

Further, as shown in FIGS. 1 and 3, the processing block B2 is provided with ducts 23 and 43 in the left sub-block B21 and the right sub-block B22, respectively. Specifically, in the left sub-block B21, the duct 23 is provided between the resist film formation unit COT and the carrier block B1 in a plan view. In the right sub-block B22, the duct 43 is provided between the development unit DEV and the interface block B3 in a plan view.

The duct 23 extends in an up-down direction, that is, the vertical direction, and is provided so as to span the first to sixth layer blocks L1 to L6. In addition, six resist film formation units COT (specifically, filter units F described later) as the liquid processing units are connected to the duct 23 from a lower end to an upper end thereof. The six resist film formation units COT are connected to different positions in the up-down direction of the duct 23 (that is, a longitudinal direction of the duct 23). On the other hand, the duct 43 extends in the up-down direction, that is, the vertical direction, and is provided so as to span the first to sixth layer blocks P1 to P6. In addition, six developing units DEV as the liquid processing units are connected to the duct 43 from a lower end to an upper end thereof. The six developing units DEV are connected to different positions in the up-down direction of the duct 43 (that is, a longitudinal direction of the duct 43).

The ducts 23 and 43 supply clean air from an air conditioner S as an air source to each liquid processing unit. The clean air supplied from the air conditioner S to the ducts 23 and 43 is adjusted to have a predetermined temperature and humidity. The predetermined temperature is, for example, room temperature or lower, specifically, 20 degrees C. to 23 degrees C. The filter unit F is provided at an upper portion of each of the resist film formation units COT and the developing units DEV to which the clean air is supplied from the ducts 23 and 43. The filter unit F includes, for example, an ultra-low penetration air (ULPA) filter or a guide plate. The filter unit F purifies air blown by a fan from the air conditioner S using the ULPA filter and supplies the purified air toward the cup 32 in, for example, a downward flow (down-flow) by the guide plate. Upstream ends of the filter units F of the liquid processing units are connected to the ducts 23 and 43, respectively. Specifically, the upstream ends of the filter units F of the liquid processing units are connected to the ducts 23 and 43 via dampers (see reference symbol D in FIG. 7). Each filter unit F may include the damper. One end of each of flexible pipes S1 and S2 used as connecting pipes is connected to each of lower end portions of the ducts 23 and 43, which are upstream ends of the ducts 23 and 43. That is, air is introduced into the ducts 23 and 43 from the lower end portions of the ducts 23 and 43 via the flexible pipes S1 and S2. The above-mentioned air conditioner S is connected to the other end of each of the flexible pipes S1 and S2.

Further, the processing block B2 is provided with fan filter units (FFUs) 24 and 44 on upper surfaces of the left sub-block B21 and the right sub-block B22, respectively. The FFUs 24 and 44 include fans 24a and 44a and filters 24b and 44b, respectively.

The fans 24a and 44a intake ambient air around the coating-developing apparatus 1. Specifically, the fans 24a and 44a intake upper ambient air around the coating-developing apparatus 1. The filters 24b and 44b remove foreign substances from the ambient air intaken by the fans 24a and 44a, respectively. In other words, the filters 24b and 44b purify the intaken ambient air.

Further, the FFUs 24 and 44 are connected to transfer-area ducts 25 and 45, respectively. The transfer-area duct 25 extends in the up-down direction and is provided so as to span the first to sixth layer blocks L1 to L6 in the left sub-block B21. Six transfer areas M (specifically, filter units G of the six transfer areas M, which will be described later) are connected to the transfer-area duct 25 from a lower end portion to an upper end portion thereof. On the other hand, the transfer-area duct 45 extends in the up-down direction and is provided so as to span the first to sixth layer blocks L1 to L6 in the left sub-block B21. In addition, six transfer areas Q (specifically, filter units G of the six transfer areas Q, which will be described later) are connected to the transfer-area duct 45 from a lower end portion an upper end portion thereof.

The filter unit G is provided at an upper portion of each of the transfer areas M and Q to which the air is supplied from the transfer-area ducts 25 and 45. The filter unit G includes, for example, the ULPA filter or the guide plate, like the filter unit F. The filter units G purify the air blown by the fans 24a and 44a of the FFUs 24 and 44 using the ULPA filters and supply the purified air to the transfer areas M and Q in, for example, a downward flow (down-flow) by the guide plates. Respective upstream ends of the filter units G of the transfer areas M and Q are connected to the transfer-area ducts 25 and 45. The FFUs 24 and 44 and the transfer-area ducts 25 and 45 constitute at least a portion of an intake supply. The intake supply intakes the ambient air around the coating-developing apparatus 1 to supply the same to the transfer areas M and Q.

In addition, in order to set internal pressures of the transfer area M, the liquid processing unit, and the delivery tower 51 (that is, the delivery unit CPL) in descending order of the liquid processing unit, the transfer area M and the delivery tower, the transfer area M, the liquid processing unit, and the delivery tower 51 are exhausted by respective built-in internal exhaust units (not shown), or air is supplied to the interiors of the transfer area M, the liquid processing unit, and the delivery tower 51.

As shown in FIG. 6, electrical component boxes 26 and 46 in which electrical components for operating various kinds of units in the processing block B2 are accommodated, are provided on the upper surfaces of the left sub-block B21 and the right sub-block B22, respectively.

Further, as shown in FIGS. 6 and 7, the duct 23 and the FFU 24 are connected to each other by a supply pipe 27. That is, the supply pipe 27 that guides air from the duct 23 to the FFU 24 is provided. As a result, in addition to the ambient air around the coating-developing apparatus 1 intaken by the FFU 24, the air from the air conditioner S flowing through the duct 23 is also supplied to the transfer area M via the FFU 24. An end portion of the supply pipe 27 on the side of the FFU 24 is provided, for example, above the fan 24a of the FFU 24 so as to discharge the air horizontally. As a result, the air from the supply pipe 27 is intaken by the fan 24a via an opening above the fan 24a.

An end portion of the supply pipe 27 on the side of the duct 23 is connected to a downstream side of a connection portion where the duct 23 is connected to the resist film formation unit COT. Specifically, the end portion of the supply pipe 27 on the side of the duct 23 is connected to a portion higher than the connection portion where the duct 23 is connected to the resist film formation unit COT at the highest position. More specifically, the end portion of the supply pipe 27 on the side of the duct 23 is connected to an upper end portion of the duct 23. The supply pipe 27 may be provided with a damper 27a as a flow rate regulating valve that regulates a flow rate of the air supplied from the duct 23 to the FFU 24 via the supply pipe 27.

As shown in FIG. 1, the interface block B3 is provided with the delivery tower 51 at a position adjacent to the transfer area Q of the left sub-block B21 in the depth direction (the Y-direction in the drawing). The delivery tower 51 is provided with a plurality of delivery units stacked one above another in the up-down direction. The delivery tower 51 is provided with delivery units TRS at height positions corresponding to the first to sixth layer blocks P1 to P6 of the right sub-block B22.

Further, the interface block B3 is provided with a transfer unit 52 on the side of the exposure apparatus E (the positive X-direction in the drawing). The transfer unit 52 includes a transfer arm 52a configured to be extendible, vertically movable, rotatable about a vertical axis, and movable in the depth direction (the Y-direction in the drawing). The transfer arm 52a may transfer the wafer W between the delivery tower 51 and the exposure apparatus E.

The coating-developing apparatus 1 configured as above is provided with at least one controller 100. The controller 100 processes computer-executable instructions that cause the coating-developing apparatus 1 to execute various processes described in the present disclosure. The controller 100 may be configured to control individual constituent elements of the coating-developing apparatus 1 to execute various processes described herein. In one embodiment, a part or the entirety of the controller 100 may be included in the coating-developing apparatus 1. The controller 100 may include a processor, a storage, and a communication interface. The controller 100 is implemented by, for example, a computer. The processor may be configured to read, from the storage, programs for providing logics or routines that enable various control operations and to perform various control operations by executing the read programs. These programs may be stored in the storage in advance or may be acquired via a medium when necessary. The acquired programs are stored in the storage and are read from the storage by the processor and executed. The medium may be various storage media H that are readable by a computer or may be a communication line connected to the communication interface. The storage medium H may be transitory or non-transitory. The processor may be a central processing unit (CPU) or one or more circuits. The storage may include a random access memory (RAM), a read only memory (ROM), a hard disk drive (HDD), a solid state drive (SSD), or a combination thereof. The communication interface may communicate with the coating-developing apparatus 1 via a communication line such as a local area network (LAN).

Next, in a coating-developing process performed by the coating-developing apparatus 1 configured as described above, for example, the wafer W is subjected to a cooling process as the temperature adjustment process by the delivery unit CPL, a resist film formation process by the resist film formation unit COT, and heat treatment (pre-exposure bake process) by the heat treatment unit of the vertical unit T in the named order. Subsequently, the wafer W is subjected to an exposure process by the exposure apparatus E. In the coating-developing process, the wafer W after exposure is subjected to heat treatment (post-exposure bake process) by the heat treatment unit of the vertical unit U and a development process by the development unit DEV. As a result, a resist pattern is formed on the wafer W.

During the coating-developing process, in addition to the ambient air around the coating-developing apparatus 1 intaken by the FFU 24, the air from the air conditioner S flowing through the duct 23 is also supplied to the transfer area M via the FFU 24.

### Main Effects of Present Embodiment

As described above, in the present embodiment, the coating-developing apparatus 1 includes the duct 23 that supplies the air from the air conditioner S to the resist film formation unit COT as the liquid processing unit, and the intake supply equipped with the FFU 24 that in takes the ambient air around the coating-developing apparatus 1 to supply the same to the transfer area M. In the present embodiment, the coating-developing apparatus 1 further includes the supply pipe 27 that connects the duct 23 and the intake supply (specifically, the FFU 24) so that the air from the air conditioner S flowing through the duct 23 is supplied to the transfer area M. Thus, the air, which is supplied from the intake supply to the transfer area M and reaches the processing unit (specifically, the delivery unit CPL) around the transfer area M, is a mixed air of the ambient air intaken from around the coating-developing apparatus 1 and the air that flows through the duct 23 but is not supplied to the resist film formation unit COT. A temperature of the ambient air intaken from around the coating-developing apparatus 1 increases due to the influence of a high-temperature component (for example, the electrical component box 26, or the like) around the intake supply, which exceeds room temperature (23 degrees C.). In contrast, the air flowing through the duct 23, which is supplied from the air conditioner S, has been adjusted to a temperature below the room temperature, and is less susceptible to the influence of the high-temperature component. Therefore, the temperature of the air supplied to the transfer area M is high, which makes it possible to suppress processing results by the processing unit around the transfer area M from becoming non-uniform in the plane of the wafer W (specifically, the adjustment of the temperature to a temperature equal to or below the room temperature by the delivery unit CPL may be suppressed from becoming non-uniform in the plane of the wafer W). That is, the processing results by the processing unit around the transfer area M may be suppressed from being affected by heat around the intake supply via the air supplied to the transfer area M. In the present embodiment, the duct 23 capable of lowering the temperature of the air supplied to the transfer area M is used to supply the air to the resist film formation unit COT. Therefore, according to the present embodiment, it is possible to reduce the footprint of the coating-developing apparatus 1 compared to a configuration in which a duct for lowering the temperature of the air supplied to the transfer area M is provided separately from the duct 23 used to supply the air to the resist film formation unit COT. In addition, in the present embodiment, instead of the air supplied from the air conditioner S via the duct 23, a mixed air of the air flowing through the duct 23 and the air around the transfer area M is supplied to the transfer area M. Thus, even if the flow rate of the air supplied from the air conditioner S via the duct 23 is low, a sufficient flow rate of air may be supplied to the transfer area M.

The present inventors measured the temperature of the wafer W after being adjusted by the delivery unit CPL in each of a case in which air, the temperature and humidity of which are adjusted (hereinafter sometimes referred to as a “temperature/humidity-adjusted air”), was not supplied to the FFU 24, a case in which the temperature/humidity-adjusted air is directly supplied to the FFU 24 at a low flow rate, and a case in which the temperature/humidity-adjusted air is directly supplied to the FFU at a high flow rate. In each case, a set temperature of the cooling plate C PLp of the delivery unit CPL was 21 degrees C., and the temperature of the air from the air conditioner S was 22 degrees C.

In this experiment, in the case in which the temperature/humidity-adjusted air was not supplied to the FFU 24, an in-plane temperature variation (3σ) of the wafer W was 0.19 degrees C. or more. In contrast, in the case in which the temperature/humidity-adjusted air was directly supplied to the intake supply at the low flow rate or the high flow rate, the in-plane temperature variation of the temperature adjustment plate was 0.165 degrees C. or less and 0.16 degrees C. or less, respectively.

In the present embodiment, while the temperature/humidity-adjusted air has been supplied to the FFU 24 via the duct 23 instead of directly supplying the air to the FFU 24, it is considered that the same results as those of the above experiment are obtained.

In addition, in the present embodiment, the end portion of the supply pipe 27 on the side of the duct 23 is connected to the downstream side of the connection portion where the duct 23 is connected to the resist film formation unit COT, specifically, the downstream side of the connection portion where the duct 23 is connected to the resist film formation unit COT of the highest layer block (the sixth layer block P6). Therefore, by supplying the air flowing through the duct 23 to the intake supply, it is possible to suppress the influence on the supply of the air to the resist film forming unit COT from the duct 23. Further, for example, in a case in which the end portion of the supply pipe 27 on the side of the duct 23 is connected between the connection portion of the duct 23 with the resist film formation unit COT of the sixth layer block P6 and the connection portion of the duct 23 with the resist film formation unit COT of the fifth layer block P5, the following concerns occur. That is, when a flow rate of air supplied from the duct 23 to the FFU 24 via the supply pipe 27 is adjusted by the damper 27a, the balance of the flow rate of the air supplied to the resist film formation unit COT via the duct 23 between the first to sixth layer blocks P1 to P6 may collapse. The present embodiment may eliminate such a matter.

Further, in the present embodiment, the intake supply includes the fan 24a. Therefore, the mixed air of the ambient air around the coating-developing apparatus 1 and the air supplied via the duct 23, which are supplied from the intake supply to the transfer area M, may be stirred. This makes it possible to suppress a variation in temperature and humidity of the mixed air supplied from the intake supply to the transfer area M.

As described above, the supply pipe 27 may be provided with the damper 27a. By providing the damper 27a in the supply pipe 27, the temperature of the mixed air may be adjusted.

### <Modifications of Supply Pipe and Duct>

In the above examples, the end portion of the supply pipe 27 on the side of the FFU 24 (that is, an air outlet from the supply pipe 27 to the intake supply including the FFU 24) is provided above the fan 24a of the FFU 24 so as to blow the air horizontally and so as not to blow the air toward the fan 24a. However, in a supply pipe 27A shown in FIG. 8, an end portion of the supply pipe 27A on the side of the FFU 24 may face the fan 24a to blow the air toward the fan 24a. Thus, the air blown from the supply pipe 27A may be efficiently intaken by the FFU 24. This makes it possible to lower the temperature of the air supplied from the FFU 24 to the transfer area M to approach the room temperature. This makes it possible to more efficiently suppress the processing results by the processing unit around the transfer area M from becoming non-uniform in the plane of the wafer W due to the influence of the temperature of the air supplied to the transfer area M.

In addition, when the end portion of the supply pipe 27A on the side of the FFU 24 faces the fan 24a, the end portion of the supply pipe 27A may be located on the side of the transfer-area duct 25 in a plan view. More specifically, the end portion of the supply pipe 27A may be located to face the transfer-area duct 25. With this configuration, the temperature/humidity-adjusted air blown from the end portion of the supply pipe 27A on the side of the FFU 24 may be efficiently introduced into the transfer-area duct 25, and a required flow rate of air may flow into the transfer-area duct 25 by the fan 24a. Therefore, the temperature of the air supplied to the transfer area M via the transfer-area duct 25 may be lowered.

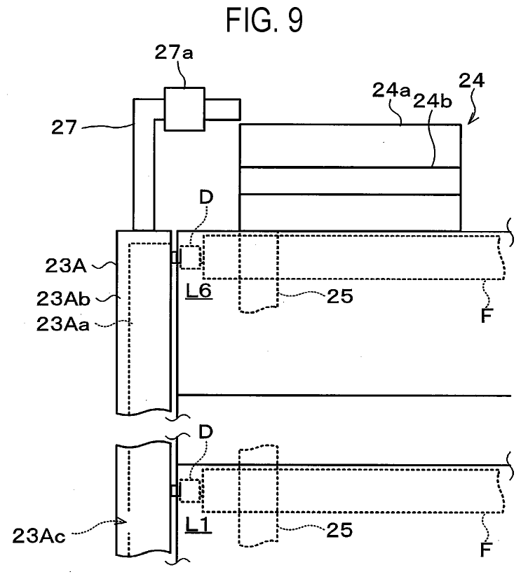

As shown in FIG. 9, a duct 23A that supplies the air to the resist film formation unit COT may be a double duct. Specifically, the duct 23A may include an inner duct 23Aa through which the air supplied from the air conditioner S flows to the resist film formation unit COT, and an outer duct 23Ab that covers the inner duct 23Aa and through which air that is not supplied to the resist film formation unit COT out of the air supplied from the air conditioner S flows. In this case, the air flowing between the outer duct 23Ab and the inner duct 23Aa functions as a heat insulating layer with respect to the inner duct 23Aa. Thus, the temperature of the air flowing through the inner duct 23Aa and supplied to the resist film formation unit COT may be suppressed from increasing due to the influence of the high-temperature components outside the duct 23A (for example, the liquid feeding unit or the electrical component in the accommodation area 14).

Therefore, it is possible to suppress the occurrence of a temperature difference and a humidity difference due to the temperature difference, which are caused by a difference in residence time inside the duct 23A between the air supplied to the resist film formation unit COT connected to an upstream side of the duct 23A and the air supplied to the resist film formation unit COT connected to a downstream side of the duct 23A. Accordingly, it is possible to suppress the processing results from being different from each other due to the temperature difference or the humidity difference between the resist film formation unit COT connected to the upstream side of the duct 23A and the resist film formation unit COT connected to the downstream side of the duct 23A.

The flow rate of the air flowing through the outer duct 23Ab is, for example, 10% or less of the amount of the air supplied to the duct 23A.

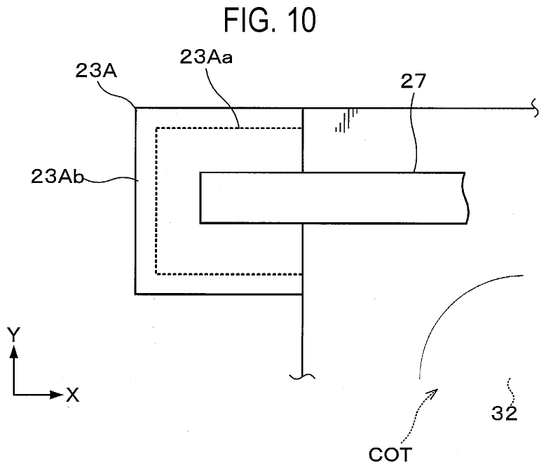

In the case of the duct 23A, as shown in FIG. 10, the outer duct 23Ab may cover, among outer wall surfaces of the inner duct 23Aa, surfaces except for the side of the resist film formation unit COT in a plan view. Specifically, in a plan view, the outer duct 23Ab may cover three outer wall surfaces among the outer wall surfaces of the inner duct 23Aa, that is, an outer wall surface on the side of the carrier block B1, an outer wall surface on the front side (the negative Y-direction in the drawing), and an outer wall surface on the rear side (the positive Y-direction in the drawing). This makes it possible to more effectively suppress the temperature of the air flowing through the inner duct 23Aa and supplied to the resist film formation unit COT from increasing due to influence outside the duct 23A.

In the duct 23A, for example, an introduction port 23Ac is provided in a lower portion of the inner duct 23Aa, which is an upstream portion of the inner duct 23Aa, to introduce the air from the interior of the inner duct 23Aa into the outer duct 23Ab. The air from the air conditioner S is supplied to the lower portion of the inner duct 23Aa. A portion of the air is introduced into the outer duct 23Ab via the introduction port 23Ac. Therefore, compared to the case in which the air conditioner S is individually connected to each of the inner duct 23Aa and the outer duct 23Ab, that is, compared to the case in which the inner duct 23Aa and the outer duct 23Ab are individually connected to the air conditioner S via different flexible pipes, piping may be simplified and an increase in footprint may be suppressed.

In addition, the introduction port 23Ac is located, for example, below a connection portion of the inner duct 23Aa with the resist film formation unit COT of the first layer block L1, which is the lowest liquid processing unit, that is, is located upstream of the connection portion of the inner duct 23Aa with the most-upstream liquid processing unit.

Unlike the present example, in a configuration in which the introduction port 23Ac is located downstream of the connection portion of the inner duct 23Aa with the most-upstream liquid processing unit, the air may flow backward. Specifically, the air introduced from the inner duct 23Aa to the outer duct 23Ab via the introduction port 23Ac may flow to the vicinity of the most-upstream liquid processing unit in the outer duct 23Ab, return to the introduction port 23Ac, and flow through the inner duct 23Aa again. By providing the introduction port 23Ac at the position as in the present example, it is possible to suppress the air from flowing backward.

In the duct 23A, for example, the outer duct 23Ab is connected to the FFU 24, and the air from the outer duct 23Ab is intaken by the FFU 24. In this case, the air flowing through the outer duct 23Ab may be effectively used. In particular, the temperature/humidity-adjusted air, which is produced with a cost, may be effectively utilized.

While the air flowing through the outer duct 23Ab is affected by external heat outside the outer duct 23Ab, the air intaken by the FFU 24 is not affected by such external heat.

In the duct 23 without the outer duct as shown in FIG. 7 or the like, in a case in which no air is supplied to the liquid processing unit from a portion of the duct 23 opposite to the air conditioner S (an upper portion in the example shown in the drawing) as in the case in which the liquid processing unit is not connected to a position corresponding to a downstream side of the duct 23, it is possible to suppress air from stagnating in the opposite portion inside the duct 23. As a result, the air, the temperature and humidity of which are adjusted during the stagnation, is suppressed from being supplied to the liquid processing unit on the side of the air conditioner S (a lower portion in the example shown in the drawing).

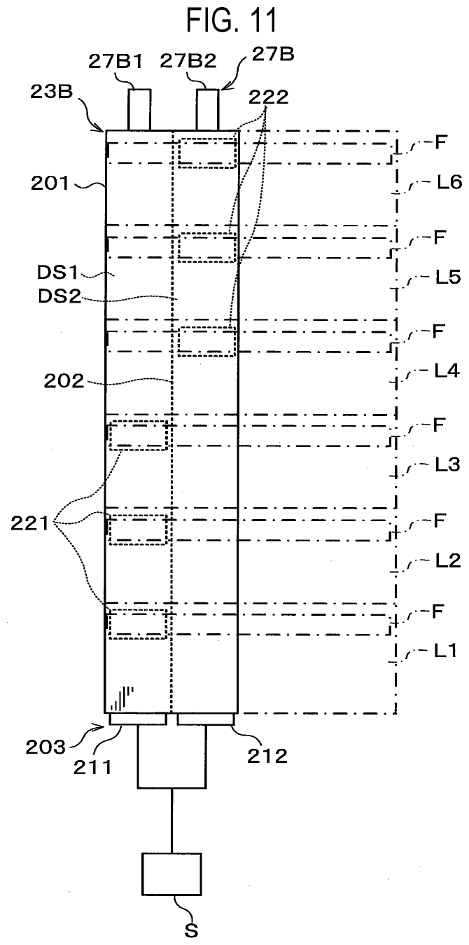

As shown in FIG. 11, a duct 23B that supplies air to the resist film formation unit COT may be provided with a duct body 201, a partition member 202, and an introducer 203.

The duct body 201 is formed in a tubular shape (specifically, a rectangular tube shape) with a bottom and a cover. The duct body 201 may include a tubular member with no bottom and no cover, a ceiling cover member that closes an upper opening of the tubular member, and a bottom cover member that closes a lower opening of the tubular member.

The partition member 202 extends in a longitudinal direction of the duct 23B, that is, in the up-down direction, and partitions an internal space of the duct 23B into a first duct space DS1 and a second duct space DS2. Specifically, the partition member 202 partitions the internal space of the duct body 201 into the first duct space DS1 and the second duct space DS2. In an example shown in the drawing, the partition member 202 partitions the internal space of the duct 23B (specifically, the internal space of the duct body 201) throughout the up-down direction so that air does not flow between the first duct space DS1 and the second duct space DS2.

The introducer 203 introduces the air (specifically, the temperature/humidity-adjusted air) from the air conditioner S functioning as the air source into each of the first duct space DS1 and the second duct space DS2. For example, the introducer 203 includes a first introduction pipe 211 as a first introducer that introduces the air from the air conditioner S into the first duct space DS1, and a second introduction pipe 212 as a second introducer that introduces the air from the air conditioner S into the second duct space DS2. That is, for example, in the duct 23B, the first duct space DS1 and the second duct space DS2 have different air intake ports so that the air from the air conditioner S is introduced independently into each of the first duct space DS1 and the second duct space DS2. The introducer 203 includes introduction ports (not shown) provided at positions corresponding respectively to the first introduction pipe 211 and the second introduction pipe 212 on a bottom wall of the duct body 201.

The duct 23B, an internal space of which is defined by the partition member 202, supplies the air flowing through the first duct space DS1 and the air flowing through the second duct space DS2 to different resist film formation units COT. Specifically, the duct 23B supplies the air flowing through the first duct space DS1 to a plurality of resist film formation units COT located on a lower side and then supplies the air flowing through the second duct space DS2 to a plurality of resist film formation units COT located on an upper side. More specifically, the duct 23B supplies the air flowing through the first duct space DS1 to the filter units F of the resist film formation units COT of the first to third layer blocks L1 to L3 and supplies the air flowing through the second duct space DS2 to the filter units F of the resist film formation units COT of the fourth to sixth layer blocks L4 to L6.

To do this, on a sidewall of the duct body 201 of the duct 23B on the side of the resist film forming unit COT, supply ports 221 are provided at positions corresponding to the first to third layer blocks L1 to L3 on the side of the first duct space DS1, and supply ports 222 are provided at positions corresponding to the fourth to sixth layer blocks L4 to L6 on the side of the second duct space DS2. The air flowing through the first duct space DS1 is supplied from the supply port 221 to the filter units F of the resist film formation units COT of the first to third layer blocks L1 to L3. The air flowing through the second duct space DS2 is supplied from the supply port 222 to the filter units F of the resist film formation units COT of the fourth to sixth layer blocks L4 to L6.

Unlike the present example, when the air is supplied from one internal space of the duct to all layers of the first to sixth layer blocks L1 to L6 in which the resist film formation units COT are provided, the one internal space needs to have a cross-sectional area corresponding to the total air blowing volume for all layers, that is, six layers. For this reason, an airflow volume of the air flowing through the duct is slow at downstream positions of the duct (specifically, the positions of the fourth to sixth layer blocks L4 to L6).

In contrast, the duct 23B of the present example supplies the air flowing through the first duct space DS1 and the air flowing through the second duct space DS2 to different resist film formation units COT. Specifically, the duct 23B supplies the air flowing through the first duct space DS1 to the first to third layer blocks L1 to L3, and supplies the air flowing through the second duct space DS2 to the fourth to sixth layer blocks L4 to L6. Therefore, in an example different from the present example, a cross-sectional area of the second duct space DS2 through which the air is supplied to the downstream positions may be limited to an area corresponding to the total air blowing volume for some of the first to sixth layer blocks L1 to L6 (specifically, three layers of the fourth to sixth layer blocks L4 to L6) rather than for all layers. Thus, the airflow volume flowing through the duct 23B may be increased at the downstream positions of the duct 23B (specifically, the positions of the fourth to sixth layer blocks L4 to L6). As a result, since the air supplied to the filter units F of the layers located on the downstream side of the duct 23B (specifically, the fourth to sixth layer blocks L4 to L6) stays in the duct 23B for a short period of time, the air in the duct 23B is hard to be affected by the external heat. This makes it possible to reduce a difference in temperature and humidity of the air between the first to sixth layer blocks L1 to L6.

Unlike the present example, even in the case in which the air is supplied from one internal space of the duct to all layers of the first to sixth layer blocks L1 to L6 in which the resist film formation units COT are provided and the duct 23B of the present example is used, an opening degree (angle) of the damper D (see FIG. 7) of each layer is adjusted. This is to suppress the difference in the air blowing volume between the layers, that is, maintain an air blowing balance between the layers. However, unlike the present example, in the case in which the air is supplied from one internal space of the duct to all layers, it is necessary to reduce the opening degree of the damper D in the upstream layer, especially the most-upstream layer (specifically, the first layer block L1) in order to suppress the difference in the air blowing volume between the layers. For example, the opening degrees of the dampers D in the first layer block L1 to the sixth layer block L6 need to be set to 20%, 40%, 50%, 70%, 80%, and 100%, respectively.

In contrast, in the case in which the duct 23B of the present example is used, air introduction ports are different from each other in the first duct space DS1 through which the air supplied to the upstream layers in an example different from the present example passes and in the second duct space DS2 through which the air supplied to the downstream layers in an example different from the present example passes. In addition, the air is introduced separately into the first duct space DS1 and the second duct space DS2. Therefore, even if the opening degrees of the dampers D in the upstream layers are small, the difference in the air blowing volume between the layers may be suppressed. For example, the opening degrees of the dampers D in the first layer block L1 to the sixth layer block L6 may be set to 70%, 80%, 100%, 70%, 80%, 100%, respectively. This makes it possible to suppress the difference in the air blowing volume between the layers.

Therefore, pressure loss caused by setting the opening degree of the damper D to be small may be suppressed. This makes it possible to suppress pressure loss in the entire air supply path including the FFU 24, the duct 23B, and the damper D. In addition, by suppressing the pressure loss in this way, the temperature/humidity-adjusted air may be supplied to the resist film formation unit COT at a high flow rate, making it easy to maintain the internal temperature and internal humidity of the resist film formation unit COT at an appropriate level. Further, by suppressing the pressure loss as described above, even if the flow rate of the temperature/humidity-adjusted air from the air conditioner S is low, the flow rate of the temperature/humidity-adjusted air to be supplied to each resist film formation unit COT may be ensured. In other words, the air conditioner S may be changed to one for supplying a low flow rate of air. This reduces power and cost.

In the case of the duct 23B, the supply pipe 27B connecting the duct 23B and the FFU 24 includes, for example, a supply pipe 27B1 used for the first duct space DS1 and a supply pipe 27B2 used for the second duct space DS2. Discharge ports (not shown) are provided at positions corresponding to the supply pipes 27B1 and 27B2 on a ceiling wall of the duct body 201.

In addition, in the duct 23B, the air supplied to the FFU 24 via the duct 23B is hard to be affected by the external heat. Therefore, the air supplied to the transfer area M via the FFU 24 has a relatively low temperature. Accordingly, according to the duct 23B, the temperature of the air supplied to the transfer area M is high, which makes it possible to suppress the processing results obtained by the processing units around the transfer area M from becoming non-uniform in the plane of the wafer W.

In a case in which a plurality of FFUs is provided in one transfer area, FFU to which the air is supplied via the supply pipe 27B1 and FFU to which the air is supplied via the supply pipe 27B2 may be identical to or different from each other.

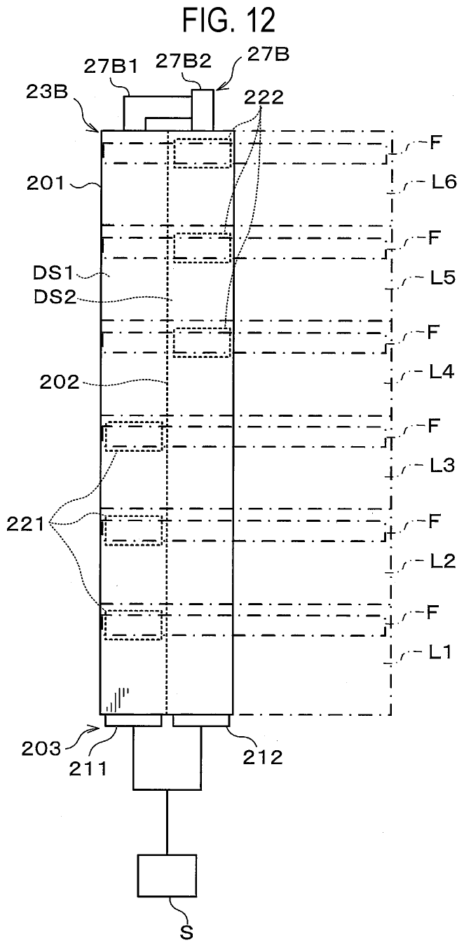

As shown in FIG. 12, the supply pipe 27B1 and the supply pipe 27B2 may be joined with each other. That is, the air flowing through the first duct space DS1 and the air flowing through the second duct space DS2 may be mixed with each other in the supply pipe 27B and supplied to the FFU 24.

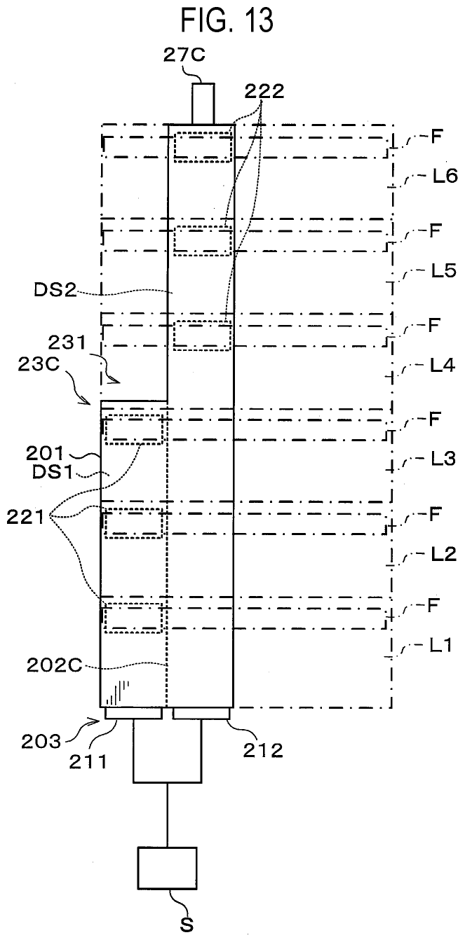

Further, as shown in FIG. 13, in a duct 23C that supplies air to the resist film formation unit COT, an internal space of a duct body 201 may be partitioned into the first duct space DS1 and the second duct space DS2 by a partition member 202C, and the first duct space DS1 may have a notch 231 which is depressed downward. The notch 231 is provided so as to span the fourth to sixth layer blocks L4 to L6 to which no air is supplied from the first duct space DS1 when viewed in the width direction of the coating-developing apparatus 1.

With this configuration, electrical components, wirings for the resist film formation unit COT, or pipes for the processing liquid may be provided in a space formed by the notch 231. This makes it possible to suppress an increase in footprint of the coating-developing apparatus 1.

In the case of the duct 23C, a supply pipe 27C connecting the duct 23C and the FFU 24 is provided only in, for example, the second duct space DS2. That is, in the case of the duct 23C, for example, the air flowing through the first duct space DS1 is not supplied to the FFU 24, and only the air flowing through the second duct space DS2 is supplied to the FFU 24.

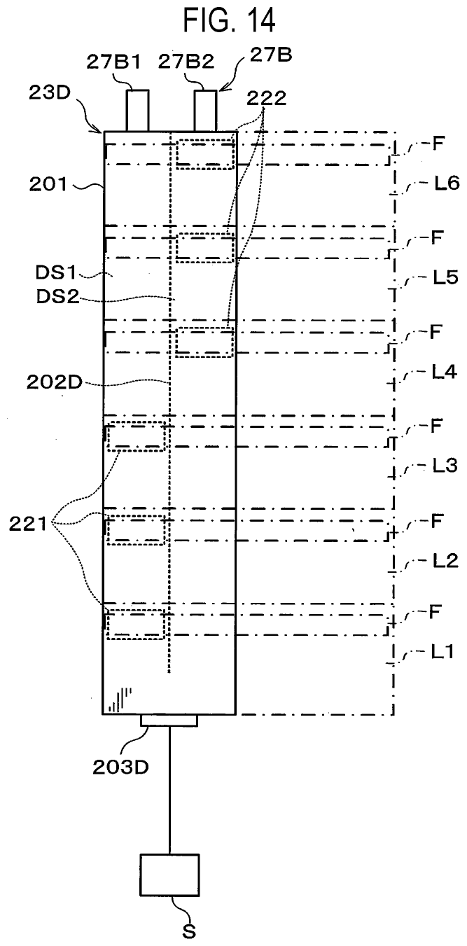

In the above examples, the partition members 202 and 202C partition the internal space of the duct body up to upstream ends (that is, lower ends) of the ducts 23B and 23C, respectively, so that no air flows between the first duct space DS1 and the second duct space DS2. However, as shown in FIG. 14, a partition member 202D may not partition an internal space of the duct body of the duct 23D at an upstream end (that is, a lower end) of the duct 23D so that the first duct space DS1 and the second duct space DS2 may be in communication with each other on an upstream side (specifically, for example, the upstream end). In the case of the duct 23D, an introducer 203D is provided common to the first duct space DS1 and the second duct space DS2 to introduce the air (specifically, the temperature/humidity-adjusted air) from the air conditioner S into each of the first duct space DS1 and the second duct space DS2.

As in the case of the duct 23B described above, in the case of the duct 23D, the difference in temperature and humidity of the air supplied to the first to sixth layer blocks L1 to L6 may be reduced.

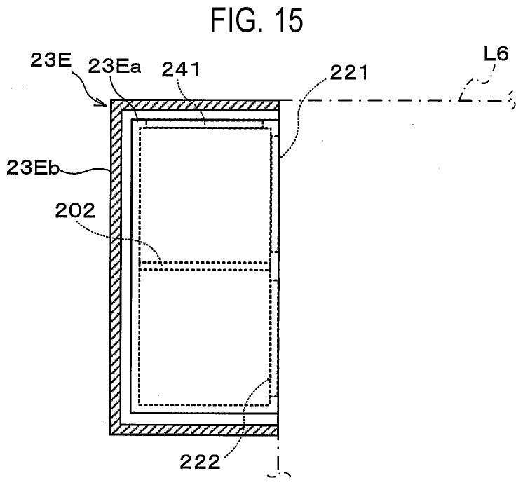

As shown in FIG. 15, a duct 23E, which supplies air to the resist film formation unit COT and has an internal space partitioned by a partition member 202, may be a double duct. Specifically, the duct 23E may include an inner duct 23Ea through which the air supplied from the air conditioner S to the resist film formation unit COT flows, and an outer duct 23Ab which covers the inner duct 23Ea and through which the air not supplied to the resist film formation unit COT out of the air supplied from the air conditioner S flows.

The inner duct 23Ea is similar in configuration to, for example, the duct 23B of FIG. 11. However, unlike the duct 23B, the inner duct 23Ea is provided with an introduction port 241 that introduces air from the first duct space DS1 into the outer duct 23Eb. For example, the introduction port 241 is provided downstream of the supply port 221 for the first layer block L1, which is the lowest layer block.

Although not shown, instead of or in addition to the introduction port 241, an introduction port that introduces air from the second duct space DS2 into the outer duct 23Eb may be provided. In this case, the introduction port may be provided downstream of the supply port 222 for the fourth layer block L4, which is the lowest layer block as a destination of the air flowing through the second duct space DS2.

In the duct 23E, for example, the outer duct 23Eb is connected to the FFU 24, and the air from the outer duct 23Eb is intaken by the FFU 24.

### <Other Modifications>

As in the case in which the duct 23 and the FFU 24 are connected to each other by the supply pipe 27, the duct 43 and the FFU 44 may be connected to each other via a supply pipe.

In the case in which the plurality of FFUs is provided in one transfer area, only an FFU close to the delivery unit CPL in a plan view may be connected to the duct 23 or the duct 43 via the supply pipe.

The duct 43 may be similar in configuration to the ducts 23A, 23B, 23C, 23D, and 23E.

In the examples shown in the drawing, the duct 23 has been described to be provided on the side of the carrier block B1. Alternatively, the duct 23 may be provided on the side of the interface block B3. This makes it possible to suppress the air in the duct 23 from being affected by the temperature of the liquid feeding unit or electrical component in the accommodation area 14 kept at the high temperature.

In the above examples, while the liquid processing unit to which the air in the ducts 23, 23A, 23B, 23C, 23D, and 23E is supplied has been described as the resist film formation unit COT, the liquid processing unit may include a liquid processing unit other than the resist film formation unit COT, such as a developing unit.

Similarly, the liquid processing unit to which the air in the duct 43 is supplied may include a liquid processing unit other than the developing unit.

According to the present disclosure in some embodiments, in a substrate processing apparatus including a processing unit configured to process a substrate and a transfer area in which a transfer unit configured to transfer the substrate to the processing unit is provided, it is possible to suppress the influence of heat from a heat source such as electrical component provided in the substrate processing apparatus while suppressing an increase in footprint. It should be noted that the embodiments disclosed herein are exemplary in all aspects and are not restrictive. The above-described embodiments may be omitted, replaced, or modified in various forms without departing from the scope and spirit of the appended claims. For example, constituent elements of the above embodiments may be arbitrarily combined. From this arbitrary combination, the operations and effects of the respective constituent elements related to the combination may be obtained, and other operations and other effects obvious to those skilled in the art may be obtained from the description of the present specification.

The effects described herein are illustrative or exemplary only and are not restrictive. That is, the technique of the present disclosure may obtain other effects obvious to those skilled in the art from the description herein in addition to or in place of the above effects.

Further, the following configurations fall within the technical scope of the present disclosure.

(1)

A substrate processing apparatus includes:
at least one processing unit configured to process a substrate;
a transfer area in which a transfer unit configured to transfer the substrate to the at least one processing unit;
a duct configured to supply air supplied from an air source to the at least one processing unit;
an intake supply configured to intake ambient air around the substrate processing apparatus to supply the air to the transfer area; and
a supply pipe configured to connect the duct and the intake supply so that the air supplied from the air source, which flows through the duct, is supplied to the transfer area.
   (2)

In the substrate processing apparatus of (1) above, an end portion of the supply pipe on a side of the duct is connected to a downstream side of a connection portion of the duct with the at least one processing unit.

(3)

In the substrate processing apparatus of (1) or (2) above, the intake supply includes:
a fan configured to intake the ambient air around the substrate processing apparatus;
a filter configured to remove foreign substances from an atmospheric gas intaken by the fan; and
a transfer-area duct configured to guide the atmospheric gas, which passes through the filter, into the transfer area.
   (4)

In the substrate processing apparatus of (3) above, an air outlet of the supply pipe blows the air toward the fan of the intake supply.

(5)

In the substrate processing apparatus of any one of (1) to (4) above, the air supplied from the air source is adjusted in temperature and humidity.

(6)

In the substrate processing apparatus of any one of (1) to (5) above, the air is introduced into the duct from a lower end portion of the duct, and an upper end portion of the duct is connected to the intake supply.

(7)

The substrate processing apparatus of any one of (1) to (6) above further includes: a delivery unit provided at a position adjacent to the transfer area in an extension direction of the transfer area in a plan view,
wherein the delivery unit includes a temperature adjustment plate on which the substrate is placed and configured to adjust a temperature of the substrate placed on the temperature adjustment plate.
   (8)

In the substrate processing apparatus of any one of (1) to (7) above, the at least one processing unit is connected to each of different positions of the duct in a longitudinal direction of the duct, and
wherein the duct includes an inner duct through which the air supplied to the at least one processing unit flows, and an outer duct configured to cover the inner duct and through which air not supplied to the at least one processing unit flows.
   (9)

In the substrate processing apparatus of (8) above, an introduction port through which the air is introduced from the inner duct into the outer duct is provided in a lower portion of the inner duct, and
wherein the air supplied from the air source is supplied to the lower portion of the inner duct, and a portion of the air is introduced into the outer duct via the introduction port.
   (10)

In the substrate processing apparatus of (8) or (9) above, the outer duct of the duct is connected to the intake supply so that the air flowing through the outer duct is introduced into the intake supply.

(11)

In the substrate processing apparatus of any one of (1) to (10) above, the duct includes:
a partition member extending in a longitudinal direction of the duct and configured to partition an internal space of the duct into a first duct space and a second duct space; and
an introducer through which the air supplied from the air source is introduced into each of the first duct space and the second duct space, and
wherein the duct supplies the air flowing through the first duct space and the air flowing through the second duct space to different processing units.
   (12)

In the substrate processing apparatus of (11) above, the at least one processing unit includes a plurality of first processing units and a plurality of second processing units,
wherein the duct supplies the air flowing through the first duct space to the plurality of first processing units located on a first side of the duct in the longitudinal direction of the duct, and supplies the air flowing through the second duct space to the plurality of second processing units located on a second side of the duct in the longitudinal direction of the duct.
   (13)

In the substrate processing apparatus of (12) above, the air supplied from the air source and introduced into the first duct space and the second duct space is adjusted in temperature and humidity.

(14)

In the substrate processing apparatus of any one of (11) to (13) above, the supply pipe includes a first supply pipe provided in the first duct space and a second supply pipe provided in the second duct space, and
wherein the first supply pipe provided in the first duct space and the second supply pipe provided in the second duct space are joined with each other.
   (15)

In the substrate processing apparatus of any one of (11) to (14) above, the partition member partitions the internal space of the duct throughout the longitudinal direction of the duct, and
wherein the introducer includes:
a first introducer configured to introduce the air supplied from the air source into the first duct space; and
a second introducer configured to introduce the air supplied from the air source into the second duct space.
   (16)

A method of intaking ambient air around a substrate processing apparatus to supply the air to a transfer area,
wherein the substrate processing apparatus includes a processing unit configured to process a substrate, the transfer area in which a transfer unit configured to transfer the substrate to the processing unit is provided, and a duct configured to supply air supplied from an air source to the processing unit,
the method comprising:
mixing air not supplied to the processing unit out of the air flowing through the duct with the ambient air intaken from around the substrate processing apparatus to supply a mixed air to the transfer area.

What is claimed is:

1. A substrate processing apparatus comprising:
at least one processing unit configured to process a substrate;
a transfer area in which a transfer unit configured to transfer the substrate to the at least one processing unit;
a duct configured to supply air supplied from an air source to the at least one processing unit;
an intake supply configured to intake ambient air around the substrate processing apparatus to supply the air to the transfer area; and
a supply pipe configured to connect the duct and the intake supply so that the air supplied from the air source, which flows through the duct, is supplied to the transfer area.

2. The substrate processing apparatus of claim 1, wherein an end portion of the supply pipe on a side of the duct is connected to a downstream side of a connection portion of the duct with the at least one processing unit.

3. The substrate processing apparatus of claim 1, wherein the intake supply includes:
a fan configured to intake the ambient air around the substrate processing apparatus;
a filter configured to remove foreign substances from an atmospheric gas intaken by the fan; and
a transfer-area duct configured to guide the atmospheric gas, which passes through the filter, into the transfer area.

4. The substrate processing apparatus of claim 3, wherein an air outlet of the supply pipe blows the air toward the fan of the intake supply.

5. The substrate processing apparatus of claim 1, wherein the air supplied from the air source is adjusted in temperature and humidity.

6. The substrate processing apparatus of claim 1, wherein the air is introduced into the duct from a lower end portion of the duct, and
wherein an upper end portion of the duct is connected to the intake supply.

7. The substrate processing apparatus of claim 1, further comprising:
a delivery unit provided at a position adjacent to the transfer area in an extension direction of the transfer area in a plan view,
wherein the delivery unit includes a temperature adjustment plate on which the substrate is placed and configured to adjust a temperature of the substrate placed on the temperature adjustment plate.

8. The substrate processing apparatus of claim 1, wherein the at least one processing unit is connected to each of different positions of the duct in a longitudinal direction of the duct, and
wherein the duct includes:
an inner duct through which the air supplied to the at least one processing unit flows; and
an outer duct configured to cover the inner duct and through which air not supplied to the at least one processing unit flows.

9. The substrate processing apparatus of claim 8, wherein an introduction port through which the air is introduced from the inner duct into the outer duct is provided in a lower portion of the inner duct, and
wherein the air supplied from the air source is supplied to the lower portion of the inner duct, and a portion of the air is introduced into the outer duct via the introduction port.

10. The substrate processing apparatus of claim 8, wherein the outer duct of the duct is connected to the intake supply so that the air flowing through the outer duct is introduced into the intake supply.

11. The substrate processing apparatus of claim 1, wherein the duct includes:
a partition member extending in a longitudinal direction of the duct and configured to partition an internal space of the duct into a first duct space and a second duct space; and
an introducer through which the air supplied from the air source is introduced into each of the first duct space and the second duct space, and
wherein the duct supplies the air flowing through the first duct space and the air flowing through the second duct space to different processing units.

12. The substrate processing apparatus of claim 11, wherein the at least one processing unit includes a plurality of first processing units and a plurality of second processing units,
wherein the duct supplies the air flowing through the first duct space to the plurality of first processing units located on a first side of the duct in the longitudinal direction of the duct, and supplies the air flowing through the second duct space to the plurality of second processing units located on a second side of the duct in the longitudinal direction of the duct.

13. The substrate processing apparatus of claim 12, wherein the air supplied from the air source and introduced into the first duct space and the second duct space is adjusted in temperature and humidity.

14. The substrate processing apparatus of claim 11, wherein the supply pipe includes a first supply pipe provided in the first duct space and a second supply pipe provided in the second duct space, and
wherein the first supply pipe provided in the first duct space and the second supply pipe provided in the second duct space are joined with each other.

15. The substrate processing apparatus of claim 11, wherein the partition member partitions the internal space of the duct throughout the longitudinal direction of the duct, and
wherein the introducer includes:
a first introducer configured to introduce the air supplied from the air source into the first duct space; and
a second introducer configured to introduce the air supplied from the air source into the second duct space.

16. A method of intaking ambient air around a substrate processing apparatus to supply the air to a transfer area,
wherein the substrate processing apparatus includes a processing unit configured to process a substrate, the transfer area in which a transfer unit configured to transfer the substrate to the processing unit is provided, and a duct configured to supply air supplied from an air source to the processing unit,
the method comprising:
mixing air not supplied to the processing unit out of the air flowing through the duct with the ambient air intaken from around the substrate processing apparatus to supply a mixed air to the transfer area.
